(19) United States
(12) Patent Application Publication
(10) Pub. No.: US 2023/0193064 A1
(43) Pub. Date: Jun. 22, 2023

(54) CHEMICAL INK FLOW STOPPER

(71) Applicant: Applied Materials, Inc., Santa Clara, CA (US)

(72) Inventors: Yingdong LUO, Newark, CA (US); Xiaopei DENG, San Jose, CA (US); Kang LUO, San Jose, CA (US); Rami HOURANI, Santa Clara, CA (US); Daihua ZHANG, Los Altos, CA (US); Ludovic GODET, Sunnyvale, CA (US)

(21) Appl. No.: 17/989,961

(22) Filed: Nov. 18, 2022

Related U.S. Application Data
(60) Provisional application No. 63/291,095, filed on Dec. 17, 2021.

(51) Int. Cl. C09D 11/38; B41M 5/52

(52) U.S. Cl. CPC C09D 11/38; H01L 51/0005; B41M 5/5209

(57) ABSTRACT

A method and apparatus for forming an optical device are described. The optical device is formed by depositing a plurality of ink drops on a surface of a substrate. The plurality of ink drops are contained within a chemical stopper, such that the chemical stopper surrounds each individual ink drop. The chemical stopper is configured to reduce reflow of the ink drops and is a fraction of the height of each of the ink drops. The ink drops are baked after being deposited within the chemical stoppers as liquid ink drops.

### CROSS-REFERENCE TO RELATED APPLICATIONS

This application claims the benefit of U.S. Provisional patent application Ser. No. 63/291,095, filed Dec. 17, 2021, which is incorporated by reference herein in its entirety.

### BACKGROUND

### Field

Embodiments of the present disclosure generally relate to methods and apparatus for depositing ink drops on a substrate. More specifically, the present disclosure is directed towards methods and apparatus for depositing ink drops on a substrate to form optical devices.

### Description of the Related Art

Utilizing an inkjet is generally an efficient method for depositing a thin film on a substrate. The inkjet deposits one or more ink drops on the substrate and subsequently heats or cures the ink drops. The ink drops deposited on the substrate may form one or more pixels on the substrate. The substrate may be an organic electroluminescent panel.

During deposition of the ink drops, the ink drops begin to reflow and merge together. The amount of reflow or merging may be reduced by adjusting the physical properties of the ink and/or the substrate. However, adjusting the physical properties of the ink causes limitations in the material of the ink used to form the ink drops. Ink reflow also limits the concentration of ink drops, which are therefore able to be formed on the substrate.

Therefore, what is needed in the art are methods for reducing reflow of ink drops while maintaining predetermined optical performance.

### SUMMARY

The present disclosure generally relates to methods of forming ink droplets on a substrate, suitable for use in semiconductor manufacturing. The method includes forming a plurality of chemical stoppers on a top surface of the substrate. Each chemical stopper of the plurality of chemical stoppers includes an opening. The method further includes performing a first thermal treatment on the plurality of chemical stoppers. A plurality of liquid ink drops are deposited within the openings of the chemical stoppers. A second thermal treatment is performed on the plurality of liquid ink drops to form a plurality of solid ink drops.

In another embodiment, another method of forming ink droplets on a substrate, suitable for use in semiconductor manufacturing, is described. The method includes forming a plurality of chemical stoppers on a top surface of the substrate. Each chemical stopper of the plurality of chemical stoppers forms an outline around an opening and the opening exposes the top surface of the substrate. A plurality of liquid ink drops are deposited within the openings of the chemical stoppers. A thermal treatment is performed on the liquid ink drops to form a plurality of solid ink drops. The thermal treatment includes heating the substrate to a temperature of about 50° C. to about 200° C. and each of the chemical stoppers have a first thickness of less than 100% of a second thickness of each of the solid ink drops.

In yet another embodiment, a non-transitory computer-readable medium stores instructions that, when executed by a processor, cause a computer system to perform a plurality of steps. The steps include forming a plurality of chemical stoppers on a top surface of a substrate. Each chemical stopper of the plurality of chemical stoppers includes an opening. A plurality of liquid ink drops are deposited within the openings of the chemical stoppers. A thermal treatment is performed on the liquid ink drops to cure the liquid ink drops and form a plurality of solid ink drops.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of an inkjet device, according to embodiments described herein.

FIG. 2 is a first method of forming ink drops on a substrate, according to one embodiment described herein.

FIG. 3 is a second method of forming ink drops on a substrate, according to one embodiment described herein.

FIGS. 4A-4F are schematic cross-sectional side views of an optical device during various stages of formation, according to embodiments described herein.

FIG. 5 is a schematic plan view of a portion of a substrate after forming a plurality of ink drops, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is directed towards apparatus and methods for substrate processing. More specifically, the present disclosure is directed towards methods for forming optical devices. The optical devices include a plurality of ink drops disposed on a substrate. The plurality of ink drops are deposited using an inkjet. Before formation of the plurality of ink drops, a plurality of chemical stoppers are formed on the top surface of the substrate. The plurality of chemical stoppers are configured to reduce the flow of the ink deposited during the inkjet deposition. The chemical stopper is made to be chemically compatible with the ink used in the inkjet deposition. The chemical stopper may form a border within which the ink drops are deposited. The chemical stopper therefore contains the ink drops within a designated area and improves inkjet device resolution and fidelity of the features formed by the ink drops.

Without the chemical stopper, the ink drops deposited on the substrate may reflow before the ink drops are able to be heated or cured. The reflow sometimes leads to multiple ink drops merging. Merging of the ink drops may be reduced or eliminated by changing the properties of the ink and/or the substrate. For example, high viscosity and high surface tension inks may be utilized. However, by creating a chemical stopper to contain the ink drops, a wider range of potential inks may be utilized to form the ink drops. The wider range of potential inks have a larger range of optical properties. The ink drops form a portion of a film within the chemical stoppers, such that the ink drops form film portions within the chemical stoppers. Each of the ink drops may be one or more ink droplets deposited on the substrate. The ink drops form a discrete ink film, where each ink droplet is a portion of the discrete ink film.

The chemical stopper is a fraction of the total height of the film formed by the ink drops deposited within the chemical stoppers. The chemical stoppers may be a small height and are configured to utilize surface tension to stop the ink drops from moving instead of a physical barrier. The chemical stoppers separate the ink drops, such that the ink drops do not merge after being deposited. The chemical stoppers have a height of less than about 100% of the height of each of the ink drops, such as less than about 90% of the height of each of the ink drops, such as less than about 80% of the height of each of the ink drops, such as less than about 70% of the height of each of the ink drops, such as less than about 60% of the height of each of the ink drops, such as less than about 50% of the height of each of the ink drops, such as less than about 40% of the height of each of the ink drops, such as less than about 30% of the heights of each of the ink drops, such as less than about 20% of the height of each of the ink drops. The actual height of each of the chemical stoppers is less than about 6000 nm, such as less than about 5000 nm, such as less than about 4000 nm, such as less than about 3000 nm, such as less than about 2000 nm, such as less than about 1000 nm, such as about 1 nm to about 2000 nm, such as about 1 nm to about 50 nm. Each of the ink drops has a height of about 5 nm to about 6000 nm, such as about 10 nm to about 5000 nm, such as about 50 nm to about 500 nm. In particular embodiments, the chemical stoppers have a height of less than about 50% of the height of each of the ink drops. The height of the ink drops is the height of the film formed by the ink drops within each chemical stopper. The height of the ink drops and the chemical stoppers is measured using ellipsometry or a scanning electron microscope (SEM). The height of the ink drops and the film may be measured by measuring the average thickness of the discrete ink film once the ink drops are deposited.

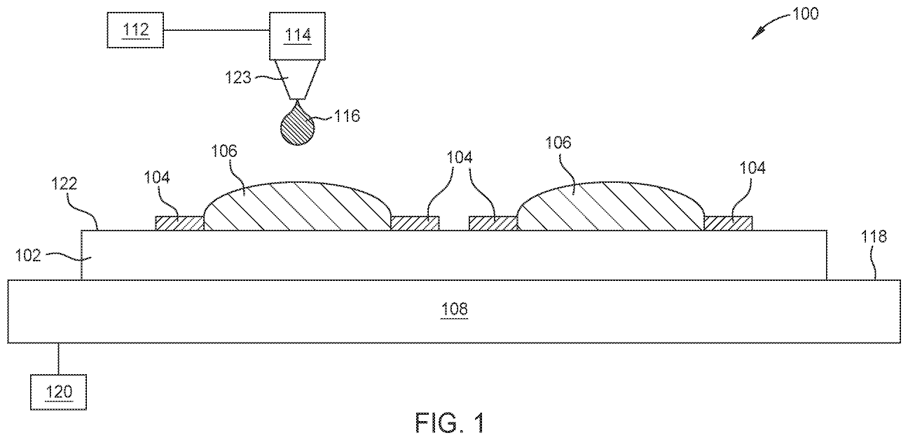

FIG. 1 is a schematic cross-sectional view of an inkjet device 100. The inkjet device 100 may also be referred to as an inkjet printer. The inkjet device 100 includes a print table 108 and an inkjet 114. The print table 108 is configured to hold a substrate 102 on which one or more optical devices are formed. The print table 108 includes a substrate support surface 118. The substrate support surface 118 is a planar top surface of the print table 108. The inkjet 114 includes a dispense nozzle 123 and an ink source 112. The dispense nozzle 123 is configured to dispense the ink 116 from the inkjet 114 and onto the substrate 102. The ink source 112 may be coupled to the inkjet 114 via one or more conduits or is directly coupled to the inkjet 114.

The ink source 112 may include more than one ink type, such that the same ink source 112 may be utilized to deposit both a plurality of chemical stoppers 104 and a plurality of ink drops 106 onto a top surface 122 of the substrate 102. The ink drops 106 are deposited within a chemical stopper 104, such that the chemical stoppers 104 are disposed around the outer circumference of each ink drop 106.

A controller 120 is coupled to one or both of the inkjet device 100 or the print table 108. The controller 120 is configured to supply instructions to the inkjet device 100. The controller 120 further receives input from sensors within the inkjet device 100. For example, the controller 120 may be configured to control output of ink from the inkjet 114 as well as movement of the print table 108. The controller 120 may also be configured to control all aspects of heating and actuation of the print table 108.

The controller 120 includes a programmable central processing unit (CPU) that is operable with a memory and a mass storage device, an input control unit, and a display unit (not shown), such as power supplies, clocks, cache, input/output (I/O) circuits, and the like, coupled to the various components of the inkjet device 100 to facilitate control of substrate processing. The controller 120 also includes hardware or software for monitoring substrate processing through sensors in the inkjet device 100, including sensors monitoring flow, RF power, electric field and the like. Other sensors that measure system parameters such as substrate temperature, chamber atmosphere pressure and the like, may also provide information to the controller 120.

To facilitate control of the inkjet device 100 and associated ink drop formation, the CPU may be one of any form of general purpose computer processor that can be used in an industrial setting, such as a programmable logic controller (PLC), for controlling various chambers and sub-processors. The memory is coupled to the CPU and the memory is non-transitory and may be one or more of readily available memory such as random access memory (RAM), read only memory (ROM), floppy disk drive, hard disk, or any other form of digital storage, local or remote. Support circuits are coupled to the CPU for supporting the processor in a conventional manner. The plasma and electric field formation and other processes are generally stored in the memory, typically as a software routine. The software routine may also be stored and/or executed by a second CPU that is remotely located from the hardware being controlled by the CPU.

The memory is in the form of computer-readable storage media that contains instructions, that when executed by the CPU, facilitates the operation of inkjet device 100. The instructions in the memory are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

In certain embodiments, the program(s) embody machine learning capabilities. Various data features include process parameters such as processing times, temperatures, pressures, voltages, polarities, powers, gas species, precursor flow rates, and the like. Relationships between the features are identified and defined to enable analysis by a machine learning algorithm to ingest data and adapt processes being performed by the inkjet device 100. The machine learning algorithms may employ supervised learning or unsupervised learning techniques. Examples of machine learning algorithms embodied by the program include, but are not limited to, linear regression, logistic regression, decision tree, state vector machine, neural network, naïve Bayes, k-nearest neighbors, K-Means, random forest, dimensionality reduction algorithms, and gradient boosting algorithms, among others.

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the controller 120 is an Ethernet for Control Automation Technology (EtherCAT) controller.

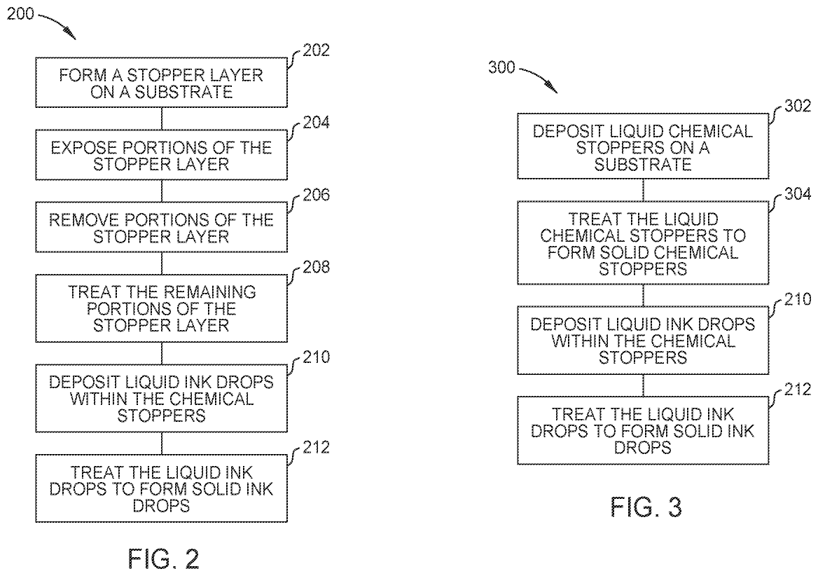

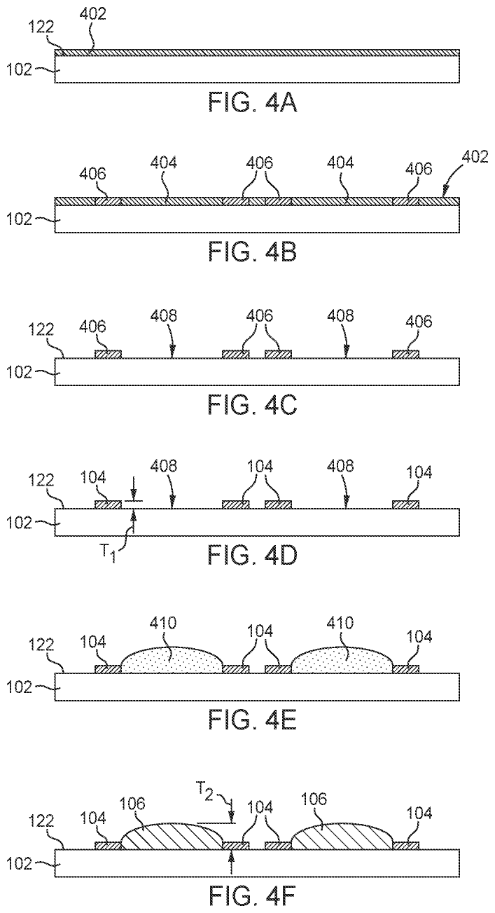

FIG. 2 is a first method 200 of forming ink drops 106 on a substrate 102. The first method 200 forms the chemical stoppers 104 using a lithography operation. The chemical stoppers 104 are formed before the formation of the ink drops 106 such that the ink drops 106 are contained within the perimeter of the chemical stoppers 104. To form the chemical stoppers 104 a stopper layer 402 is formed on the top surface 122 of the substrate 102 during a first operation 202. The stopper layer 402 formed on the substrate 102 is illustrated in FIG. 4A.

The stopper layer 402 is formed using a spin coat process, a dip-coat process, or another deposition process. The stopper layer 402 is formed of a fluorinated or silicone-based monomer, oligomer, or polymer. Examples of fluorinated monomers include 3-(Perfluorooctyl)-1,2-propenoxide (C₁₁H₅F₁₇O), 1H,1H,5H-Octafluoropentyl acrylate (C₈H₆F₈O₂), 3-(1H, 1H,5H-octafluoropentyloxy)-1,2-epoxypropane (C₈H₈F₈O₂), 2-[(2,2,3,3-Tetrafluoropropoxy)methyl]oxirane (C₆H₈F₄O₂), 2,2,3,3,4,4,5,5,6,6,7,7-Dodecafluoroheptyl acrylate (C₁₀H₆F₁₂O₂), 3,3,4,4,5,5,6,6,7,7,8,8,8-Tridecafluorooctyl acrylate (C₁₁H₇F₁₃O₂), 1H,1H,5H-Octafluoropentyl methacrylate (C₉H₈F₈O₂), 2-(Perfluorooctyl)ethyl methacrylate (C₁₄H₉F₁₇O₂), 3,3,4,4,5,5,6,6,7,7,8,8,9,9,10,10,10-Heptadecafluorodecyl acrylate (C₁₃H₇F₁₇O₂), 2,2,3,3,4,4,4-Heptafluorobutyl acrylate (C₇H₅F₇O₂), 2,2,2-Trifluoroethyl acrylate (C₅H₅F₃O₂), 2-(Perfluorodecyl)ethyl acrylate (C₁₅H₇F₂₁₀₂), 1,1,1,3,3,3-Hexafluoroisopropyl acrylate (C₆H₄F₆O₂), 2,2,3,4,4,4-Hexafluorobutyl acrylate (C₇H₆F₆O₂), and 2,2,3,3,3-Pentafluoropropyl acrylate (C₆H₅F₅O₂). The silane monomers include 3,3,3-Trifluoropropyl-trichlorosilane (C₃H₄Cl₃F₃Si) and 1H,1H,2H,2H-Perfluorooctyltriethoxysilane (C₁₄H₁₉F₁₃O₃Si). Fluorinated oligomers and polymers include any one of poly[4,5-difluoro-2,2-bis(trifluoromethyl)-1,3-dioxole-co-tetrafluoroethylene] ((C₅F₈O₂·C₂F₄)ₓ), poly(pentafluorostyrene) ((C₈H₃F₅)ₓ), Nafion Perfluorinated sulfonic acid copolymer ((C₇HF₁₃O₅S·C₂F₄)ₓ), and Poly(bis(2,2,2-trifluoroethoxy)phosphazene) ((C₄H₄F₆NO₂P)ₙ). Fluorinated oligomers and polymers further include amorphous fluoropolymers such as Teflon™ AF series resins, CYTOP® series resins, and Hyflon® perfluoropolymer resins. The stopper layer 402 may further be a Polydimethylsiloxane oligomer or polymer, such as one or more of methacryloxypropyl terminated polydimethylsiloxane ((C₂H₆OSi)ₙC₁₈H₃₄O₅Si₂); methacryloxypropyl terminated polydimethylsiloxane (C₁₂H₂₆O₄Si₂); ((Epoxycyclohexylethyl)methylsiloxane-dimethylsiloxane copolymer, viscosity 650-800 cSt.) (C₁₃H₂₈O₃Si₂); epoxycyclohexylethyl terminated polydimethylsiloxane, 25-35 cs; (epoxypropoxypropyl)dimethoxysilyl terminated polydimethylsiloxane, 80-120 cSt; mercaptopropyl terminated polydimethylsiloxane, 80-120 cSt; monomethacryloxypropyl functional polydimethylsiloxane; (methacryloxypropyl)methylsiloxane, dimethylsiloxane copolymer; and mono-(2,3-epoxy)propylether terminated polydimethylsiloxane, asymmetric, 10-15 cSt.

The fluorinated or silicon-based monomers, oligomers, and polymers may further be described using a Chemical Abstracts Service (CAS) registry number. The CAS registry number is a unique numeric identified for each compound. The CAS registry numbers associated with the fluorinated monomers described above includes 38565-53-6, 376-84-1, 19932-27-5, 19932-26-4, 2993-85-3, 17527-29-6, 355-93-1, 1996-88-9, 27905-45-9, 424-64-6, 407-47-6, 17741-60-5, 2160-89-6, 54052-90-3, and 356-86-5. The CAS registry numbers associated with the silane monomers described above includes 592-09-6 and 51851-37-7. The CAS registry numbers associated with the fluorinated oligomers and polymers described above includes 37626-13-4, 26838-55-1, 31175-20-9, and 28212-50-2. The CAS registry numbers associated with the Polydimethylsiloxane oligomers or polymers described above includes 58130-03-3, 146632-07-7, 67762-95-2,102782-98-9,188958-73-8, 308072-58-4, 868684-55-3/104780-61-2, and 127947-26-6.

The stopper layer 402 may further be formed of a self-assembled monolayer (SAM layer). The SAM layer aligns each of the molecules therein one directionally. The molecules within the SAM layer include a head group configured to be bonded to the substrate, a functional group configured to face away from the substrate, and a tail connecting the head group and the functional group. The head group is configured to bond to a material of the top surface of the substrate, such as a metal surface or an —OH molecule on the top surface. The functional group may be a thiol, such as an alkyl chain. The tail group is chosen based off the desired properties with respect to a later deposited uncured ink drop 410 (FIG. 4E). In some embodiments, the tail group is a hydrophobic moiety. The hydrophobic moiety is configured to face outward from the top surface of the substrate and therefore leads to a lower surface energy film.

The stopper layer 402 may be deposited as a solution. Therefore, the stopper layer 402 may undergo a bake operation after formation of the stopper layer on the substrate during the operation 202.

In embodiments in which the stopper layer 402 is formed on the substrate 102 using the operation 202, the stopper layer 402 is patterned during an exposure process, such that portions of the stopper layer 402 are exposed during an operation 204. The exposing of the stopper layer 402 includes exposing portions of the stopper layer 402 to radiation. During the operation 204, a plurality of first portions 404 and a plurality of second portions 406 of the stopper layer 402 are formed. The plurality of first portions 404 are exposed portions of the stopper layer 402. The plurality of second portions 406 are unexposed portions of the stopper layer 402. The plurality of first portions 404 are exposed to the radiation during the operation 204. The plurality of second portions 406 are not exposed to the radiation during the operation 204.

As shown in FIG. 4B, the second portions 406 are the portions of the stopper layer 402, which eventually become the chemical stoppers 104, such that the stopper layer 402 is a positive tone resist. Alternatively, the stopper layer 402 is a negative tone resist and the first portions 404 are configured to become the chemical stoppers 104. After exposing the stopper layer 402 to form the first portions 404 and the second portions 406, the stopper layer 402 may be baked and/or UV treated.

After baking the stopper layer 402, portions of the stopper layer 402 are removed during an operation 206. If the stopper layer 402 is a positive tone resist, the first portions 404 of the stopper layer 402 are removed as shown in FIG. 4C. If the stopper layer 402 is a negative tone resist, the second portions 406 of the stopper layer 402 are removed (not shown). Removing a portion of the stopper layer 402 is performed using one of an etch process or by dissolving a soluble portion of the stopper layer 402. The etch process is a selective etch and only etches one of the first portions 404 or the second portions 406.

Removing portions of the stopper layer 402 forms openings 408 within the stopper layer 402. The openings 408 expose at least a portion of the top surface 122 of the substrate 102. When a positive tone resist is utilized, removing portions of the stopper layer 402 forms openings 408 between each of the second portions 406 as shown in FIG. 4C. When a negative tone resist is utilized, removing portions of the stopper layer 402 forms openings 408 between the first portions 404.

Once the openings 408 are formed within the stopper layer 402, the remaining portions of the stopper layer 402 are optionally treated during an operation 208 to form the chemical stoppers 104. The chemical stoppers 104 after the treatment of operation 208 are illustrated in FIG. 4D. In embodiments wherein the stopper layer 402 is previously baked and/or UV treated after exposure of the stopper layer 402 during the operation 204, the operation 208 may be removed.

Treating the remaining portions of the stopper layer 402 may include baking the second portions 406 and/or performing an ultraviolet (UV) cure on the second portions 406. Baking and/or UV curing the remaining portions of the stopper layer forms the chemical stoppers 104. The baking and/or UV curing of the remaining portions of the stopper layer 402 removes solvent within the remaining portions of the stopper layer 402. In embodiments wherein the remaining portions of the stopper layer 402 are the first portions 404, the first portions 404 are baked and/or UV cured.

Baking the remaining portions of the stopper layer 402 during the operation 208 is performed at a bake temperature of about 50° C. to about 200° C., such as about 80° C. to about 140° C., such as about 100° C. to about 120° C.

The chemical stoppers 104 have a surface tension of less than about 35 mN/m, such as less than about 30 mN/m, such as less than about 25 mN/m, such as about 10 mN/m to about 25 mN/m. The low surface tension assists in repelling liquid ink drops, such as the liquid ink drops 410 of FIG. 4E. Lower surface energy chemicals further have lower miscibility with other organic chemicals and fluids.

The chemical stoppers 104 have a first thickness T₁. The first thickness T₁ is the distance the chemical stoppers 104 extend from the top surface 122 of the substrate 102. The first thickness T₁ is less than about 6000 nm, such as less than about 5000 nm, such as less than about 4000 nm, such as less than about 3000 nm, such as less than about 2000 nm, such as less than about 1000 nm, such as about 1 nm to about 2000 nm, such as about 1 nm to about 50 nm. In embodiments wherein the chemical stopper 104 is a SAM layer, the first thickness T₁ is about 0.5 nm to about 50 nm, such as about 0.5 nm to about 2 nm, such as about 1 nm to about 2 nm. The small thickness of the chemical stoppers 104 reduces the impact the chemical stoppers 104 have on the optical properties of the overall optical device.

After forming the chemical stoppers 104 during the operation 208, liquid ink drops 410 are deposited within the chemical stoppers 104 during an operation 210 as shown in FIG. 4E. The liquid ink drops 410 are formed of an optical material, such as one or a combination of a solvent (such as Propylene glycol methyl ether acetate (PGMEA)), a monomer (such as 1,6-Hexanediol diacrylate (HDDA) (C₁₂H₁₈O₄), or a photoinitiator (such as Diphenyl(2,4,6-trimethylbenzoyl)phosphine oxide (TPO) (C₂₂H₂₁O₂P). The liquid ink drops 410 are formed using an inkjet, such as the inkjet 114 of FIG. 1. The chemical stoppers 104 provide a barrier to reflow of the liquid ink drops 410. The liquid ink drops 410 form a film on the substrate 102, such that each individual liquid ink drop 410 forms a portion of an ink film.

The liquid ink drops 410 may have a surface tension of about 24 mN/m to about 80 mN/m, such as about 28 mN/m to about 33 mN/m. In some embodiments, the liquid ink drops 410 have a surface tension of about 50 mN/m to about 70 mN/m. The surface tension of the liquid ink drops 410 prevents reflow of the liquid ink drops 410 over the chemical stoppers 104.

The liquid ink drops 410 may have a wetting angle of less than about 100 degrees with respect to the top surface 122 of the substrate 102, such as a wetting angle of less than about 80 degrees, such as a wetting angle of less than about 40 degrees. The wetting angle of the liquid ink drops 410 with respect to the chemical stoppers 104 is increased compared to the wetting angle with respect to the top surface 122 of the substrate 102. In embodiments described herein, the wetting angle of the liquid ink drops 410 to the chemical stoppers 104 is about 40 to about 150, such as about 60 to about 120, such as about 80 to about 100.

After deposition of the liquid ink drops 410 within the chemical stoppers 104, the liquid ink drops 410 are treated during an operation 212. Treating the liquid ink drops 410 during the operation 212 includes a heat treatment, such as a baking or a UV curing operation. Once the liquid ink drops 410 are treated, the liquid ink drops 410 are formed into solid ink drops 106 as shown in FIG. 4F. The solid ink drops 106 may also be referred to as portions of an ink film or as discrete ink films.

Baking and/or UV curing the liquid ink drops 410 is performed to remove solvent from the liquid ink drops 410. Baking the liquid ink drops 410 during the operation 212 is performed at a bake temperature of about 60° C. to about 200° C., such as about 80° C. to about 140° C., such as about 100° C. to about 120° C.

The solid ink drops 106 formed during the operation 212 have a refractive index (RI) of about 1.0 to about 2.5, such as about 1.2 to about 2.3, such as about 1.3 to about 2.2. The solid ink drops 106 have a second thickness T₂ of greater than about 10 nm, such as greater than about 100 nm, such as greater than about 300 nm, such as about 300 nm to about 6000 nm, such as about 300 nm to about 5000 nm, such as about 300 nm to about 500 nm. The second thickness T₂ is the distance the solid ink drops 106 extend from the top surface 122 of the substrate 102. The second thickness T₂ of the solid ink drops 106 is the height of the film formed by the solid ink drops 106 within each chemical stopper 104. The height of the solid ink drops 106 and the chemical stoppers 104 is measured using ellipsometry or a scanning electron microscope (SEM). The height of the solid ink drops 106 and the film may be measured by measuring the average thickness of the discrete ink film once the solid ink drops 106 are deposited.

The chemical stoppers 104 therefore have a first thickness T₁ of less than about 100% of the second thickness T₂ of the solid ink drops 106, such as a first thickness T₁ of less than about 90% of the second thickness T₂ of the solid ink drops 106, such as a first thickness T₁ of less than about 80% of the second thickness T₂ of the solid ink drops 106, such as a first thickness T₁ of less than about 70% of the second thickness T₂ of the solid ink drops 106, such as a first thickness T₁ of less than about 60% of the second thickness T₂ of the solid ink drops 106, such as a first thickness T₁ of less than about 50% of the second thickness T₂ of the solid ink drops 106, such as a first thickness T₁ of less than about 30% of the second thickness T₂ of the solid ink drops 106, such as a first thickness T₁ of less than about 20% of the second thickness T₂ of the solid ink drops 106. In some embodiments, the chemical stoppers 104 have a first thickness T₁ of less than about 10% of the second thickness T₂ of the solid ink drops 106. In some embodiments, the chemical stoppers 104 have a first thickness T₁ of about 1% to about 50% of the second thickness T₂ of the solid ink drops 106, such as about 2% to about 20%. Each of the solid ink drops 106 may be one or more ink drops deposited on the substrate 102. The solid ink drops 106 form a discrete ink film, where each solid ink drop 106 is a portion of the discrete ink film. The second thickness T₂ of the solid ink drops 106 may be obtained by measuring the average thickness of the discrete ink film once the solid ink drops 106 are deposited. Similarly, the chemical stoppers 104 may be one or more drops deposited on the substrate 102. The chemical stoppers 104 form a discrete stopper film, where each chemical stopper 104 is a portion of the discrete stopper film. The first thickness T₁ of the chemical stoppers 104 may be obtained by measuring the average thickness of the discrete chemical stoppers 104 deposited on the substrate 102.

FIG. 3 is a second method 300 of forming the solid ink drops 106 on a substrate, such as the substrate 102. The method 300 utilizes an inkjet, such as the inkjet 114 to deposit each of the chemical stoppers 104 as well as the ink drops 106. The method 300 is similar to the method 200 after the formation and treatment of the chemical stoppers 104.

During the method 300, a plurality of chemical stoppers are deposited on the substrate 102 during an operation 302. The plurality of chemical stoppers are deposited using an inkjet, such as the inkjet 114. The plurality of chemical stoppers are printed onto the top surface of the substrate 102 as liquid chemical stoppers. The liquid chemical stoppers are shown as the second portions 406 of FIG. 4C.

The liquid chemical stoppers deposited during the operation 302 are formed of a fluorinated or silicone-based monomer, oligomer, or polymer. Examples of fluorinated monomers include 3-(Perfluorooctyl)-1,2-propenoxide (C11H5F17O), 1H,1H,5H-Octafluoropentyl acrylate (C8H6F8O2), 3-(1H,1H,5H-octafluoropentyloxy)-1,2-epoxypropane (C8H8F8O2), 2-[(2,2,3,3-Tetrafluoropropoxy)methyl]oxirane (C6H8F4O2), 2,2,3,3,4,4,5,5,6,6,7,7-Dodecafluoroheptyl acrylate (C10H6F12O2), 3,3,4,4,5,5,6,6,7,7,8,8,8-Tridecafluorooctyl acrylate (C11H7F13O2), 1H,1H,5H-Octafluoropentyl methacrylate (C9H8F8O2), 2-(Perfluorooctyl)ethyl methacrylate (C14H9F17O2), 3,3,4,4,5,5,6,6,7,7,8,8,9,9,10,10,10-Heptadecafluorodecyl acrylate (C13H7F17O2), 2,2,3,3,4,4,4-Heptafluorobutyl acrylate (C7H5F7O2), 2,2,2-Trifluoroethyl acrylate (C5H5F3O2), 2-(Perfluorodecyl)ethyl acrylate (C15H7F2102), 1,1,1,3,3,3-Hexafluoroisopropyl acrylate (C6H4F6O2), 2,2,3,4,4,4-Hexafluorobutyl acrylate (C7H6F6O2), and 2,2,3,3,3-Pentafluoropropyl acrylate (C6H5F5O2). The silane monomers include 3,3,3-Trifluoropropyl-trichlorosilane (C3H4Cl3F3Si) and 1H,1H,2H,2H-Perfluorooctyltriethoxysilane (C14H19F13O3Si). Fluorinated oligomers and polymers include any one of poly[4,5-difluoro-2,2-bis(trifluoromethyl)-1,3-dioxole-co-tetrafluoroethylene] (C5F8O2·C2F4)x, poly(pentafluorostyrene) (C8H3F5)x, Nafion Perfluorinated sulfonic acid copolymer (C7HF13O5S·C2F4)x, and Poly(bis(2,2,2-trifluoroethoxy)phosphazene) (C4H4F6NO2P)n. Fluorinated oligomers and polymers further include amorphous fluoropolymers such as Teflon™ AF series resins, CYTOP® series resins, and Hyflon® perfluoropolymer resins. The stopper layer 402 may further be a Polydimethylsiloxane oligomer or polymer, such as one or more of methacryloxypropyl terminated polydimethylsiloxane ((C2H6OSi)nC18H3405Si2); methacryloxypropyl terminated polydimethylsiloxane (C12H26O4Si2); ((Epoxycyclohexylethyl)methylsiloxane-dimethylsiloxane copolymer, viscosity 650-800 cSt.) (C13H28O3Si2); epoxycyclohexylethyl terminated polydimethylsiloxane, 25-35 cSt; (epoxypropoxypropyl)dimethoxysilyl terminated polydimethylsiloxane, 80-120 cSt; mercaptopropyl terminated polydimethylsiloxane, 80-120 cSt; monomethacryloxypropyl functional polydimethylsiloxane; (methacryloxypropyl)methylsiloxane, dimethylsiloxane copolymer; and mono-(2,3-epoxy)propylether terminated polydimethylsiloxane, asymmetric, 10-15 cSt.

The fluorinated or silicon-based monomers, oligomers, and polymers may further be described using a Chemical Abstracts Service (CAS) registry number. The CAS registry number is a unique numeric identified for each compound. The CAS registry numbers associated with the fluorinated monomers described above includes 38565-53-6, 376-84-1, 19932-27-5, 19932-26-4, 2993-85-3, 17527-29-6, 355-93-1, 1996-88-9, 27905-45-9, 424-64-6, 407-47-6, 17741-60-5, 2160-89-6, 54052-90-3, and 356-86-5. The CAS registry numbers associated with the silane monomers described above includes 592-09-6 and 51851-37-7. The CAS registry numbers associated with the fluorinated oligomers and polymers described above includes 37626-13-4, 26838-55-1, 31175-20-9, and 28212-50-2. The CAS registry numbers associated with the Polydimethylsiloxane oligomers or polymers described above includes 58130-03-3, 146632-07-7, 67762-95-2,102782-98-9,188958-73-8, 308072-58-4, 868684-55-3/104780-61-2, and 127947-26-6.

The liquid chemical stoppers may further be formed of a self-assembled monolayer (SAM layer). The SAM layer aligns each of the molecules therein one directionally. The molecules within the SAM layer include a head group configured to be bonded to the substrate, a functional group configured to face away from the substrate, and a tail connecting the head group and the functional group. The head group is configured to bond to a material of the top surface of the substrate, such as a metal surface or an —OH molecule on the top surface. The functional group may be a thiol, such as an alkyl chain. The tail group is chosen based off the desired properties with respect to a later deposited uncured ink drop 410 (FIG. 4E). In some embodiments, the tail group is a hydrophobic moiety. The hydrophobic moiety is configured to face outward from the top surface of the substrate and therefore leads to a lower surface energy film.

After depositing the liquid chemical stoppers during the operation 302, the liquid chemical stoppers are treated to form a plurality of solid chemical stoppers, such as the chemical stoppers 104 of FIG. 4D, during an operation 304. The liquid chemical stoppers have reduced reflow themselves due to their own surface tension and physical properties. Treating the remaining portions of the stopper layer 402 may include baking the liquid chemical stoppers and/or performing an ultraviolet (UV) cure on the liquid chemical stoppers. Baking and/or UV curing the remaining portions of the stopper layer forms the chemical stoppers 104. The baking and/or UV curing of the liquid chemical stoppers removes solvent within the liquid chemical stoppers.

Baking the liquid chemical stoppers during the operation 304 is performed at a bake temperature of about 50° C. to about 200° C., such as about 40° C. to about 140° C., such as about 60° C. to about 120° C., such as about 80° C. to about 100° C.

The chemical stoppers 104 have a surface tension of less than about 35 mN/m, such as less than about 30 mN/m, such as less than about 25 mN/m, such as about 10 mN/m to about 25 mN/m. The low surface tension assists in repelling liquid ink drops, such as the liquid ink drops 410 of FIG. 4E.

The chemical stoppers 104 have a first thickness T₁. The first thickness T₁ is the distance the chemical stoppers 104 extend from the top surface 122 of the substrate 102. The first thickness T₁ is less than about 6000 nm, such as less than about 5000 nm, such as less than about 4000 nm, such as less than about 3000 nm, such as less than about 2000 nm, such as less than about 1000 nm, such as about 1 nm to about 1000 nm, such as about 1 nm to about 50 nm. In embodiments wherein the chemical stopper 104 is a SAM layer, the first thickness T₁ is about 0.5 nm to about 50 nm, such as about 0.5 nm to about 2 nm, such as about 1 nm to about 2 nm. The small thickness of the chemical stoppers 104 reduces the impact the chemical stoppers 104 have on the optical properties of the overall optical device.

After treating the liquid chemical stoppers during the operation 304, operation 210 and operation 212 are performed in a manner similar to that previously described. The operation 210 and the operation 212 include depositing the uncured ink drops 410 within the chemical stoppers 104 and treating the uncured ink drops 410 to form the solid ink drops 106.

Similarly, to the chemical stoppers 104 formed during the method 200, the liquid ink drops 410 have a wetting angle of less than about 100 degrees with respect to the top surface 122 of the substrate 102, such as a wetting angle of less than about 80 degrees, such as a wetting angle of less than about 60 degrees. The wetting angle of the liquid ink drops 410 with respect to the chemical stoppers 104 is increased compared to the wetting angle with respect to the top surface 122 of the substrate 102. In embodiments described herein, the wetting angle of the liquid ink drops 410 to the chemical stoppers 104 is about 40 to about 150, such as about 60 to about 120, such as about 80 to about 100.

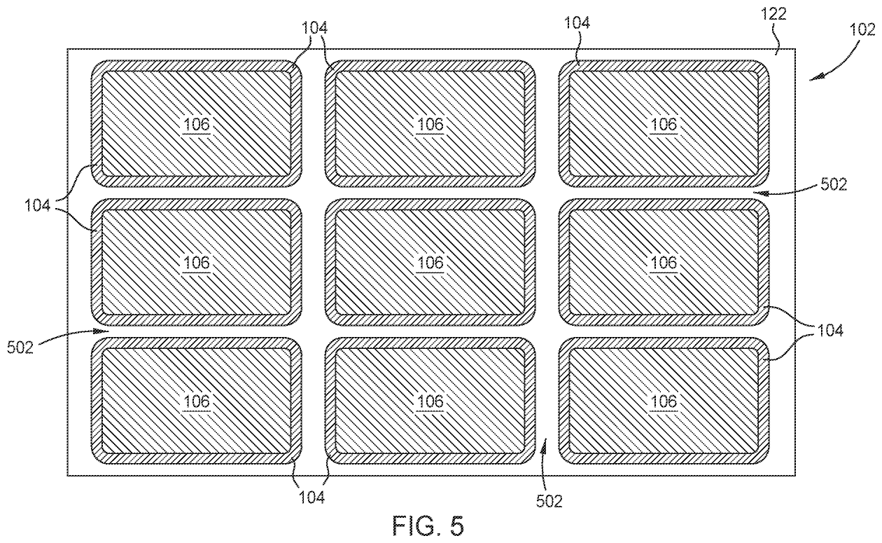

FIG. 5 is a schematic plan view of a portion of a substrate 102 after forming a plurality of ink drops 106. As shown in FIG. 5, each of the ink drops 106 are formed inside of a chemical stopper 104. The chemical stoppers 104 form a barrier around a circumference of each of the ink drops 106, such that the chemical stoppers 104 circumscribe each of the ink drops 106. The chemical stoppers 104 are formed such that the openings 408 (FIGS. 4C and 4D) are disposed within the perimeter of each of the chemical stoppers 104. The chemical stoppers 104 therefore form an outline around the openings 408 and the ink drops 106. The chemical stoppers 104 may further be shaped to manage the flow of the ink drops 106 when the ink drops 106 are deposited as liquid ink drops 410 (FIG. 4E). As shown in FIG. 5, the chemical stoppers 104 form a generally rectangular perimeter around the ink drops 106. However, in some embodiments, the chemical stoppers 104 may form other perimeter shapes. In some embodiments, the chemical stopper 104 forms a perimeter of a circle, an oval, a triangle, a pentagon, a hexagon, a heptagon, or an octagon. By modifying the deposition and shape of the chemical stoppers 104, the ink drops 106 may therefore be controlled to form different shapes. In some embodiments, the ink drops 106 form pixels. The chemical stoppers 104 assist in obtaining higher concentrations of ink drops 106 without reflow of ink drops 106. The ink drop 106 concentration is increased as ink drops 106 may be printed closer together without the ink drops 106 reflowing into one another.

The apparatus and methods described herein enable the formation of a high concentration of ink drops 106 with reduced reflow of the ink drops 106 together. The formation of the chemical stoppers 104 forms a barrier to reflow. The material of each of the chemical stoppers 104 is selected to reduce and/or eliminate flow of the liquid ink drops 410 over the chemical stoppers 104 until the liquid ink drops 410 are heat treated. The chemical stoppers 104 utilize the physical and chemical interactions between the chemical stoppers 104 and the liquid ink drops 410 to prevent reflow and therefore have a reduced thickness relative to the liquid ink drops 410. The reduced thickness of the chemical stoppers 104 reduces the impact of the chemical stoppers 104 on overall optical device performance. Methods described herein enable a greater variety of substrate material and liquid ink drop material combinations as the chemical stopper 104 is chosen to reduce reflow and the substrate material and/or the liquid ink drop material may be chosen without consideration of the reflow potential of the liquid ink drops.

Each of the chemical stoppers 104 are separated from one another by a space 502. The space 502 is a small gap on the top surface 122 of the substrate 102 between the chemical stoppers 104. In some embodiments, there are no spaces 502 between the chemical stoppers 104 and a single wall of a chemical stopper 104 is disposed between each ink drop 106. In some embodiments, the chemical stoppers 104 are formed as a grid without the spaces 502 and the ink drops 106 are formed within each opening of the grid.

While the foregoing is directed to embodiments of the present disclosure, other and further embodiments of the disclosure may be devised without departing from the basic scope thereof, and the scope thereof is determined by the claims that follow.

What is claimed is:

1. A method of forming ink droplets on a substrate, suitable for use in semiconductor manufacturing, comprising:
forming a plurality of chemical stoppers on a top surface of the substrate, wherein each chemical stopper of the plurality of chemical stoppers comprises an opening;
performing a first thermal treatment on the plurality of chemical stoppers;
depositing a plurality of liquid ink drops within the openings of the chemical stoppers; and
performing a second thermal treatment on the plurality of liquid ink drops to form a plurality of solid ink drops.

2. The method of claim 1, wherein the plurality of chemical stoppers have a first thickness of about 5 nm to about 2000 nm.

3. The method of claim 1, wherein the plurality of chemical stoppers has a surface tension of less than about 35 mN/m.

4. The method of claim 3, wherein the plurality of chemical stoppers comprises one or a combination of silicone, a fluorinated material, a polymer, or a self-assembled monolayer.

5. The method of claim 4, wherein the chemical stoppers comprise a self-assembled monolayer and include a hydrophobic moiety disposed on a side of the self-assembled monolayer facing away from the substrate.

6. The method of claim 1, wherein the solid ink drops have a refractive index of about 1.0 to about 2.5.

7. The method of claim 1, wherein the solid ink drops have a second thickness of greater than about 2 μm.

8. The method of claim 1, wherein the liquid ink drops have a surface tension of about 24 mN/m to about 80 mN/m.

9. The method of claim 1, wherein the liquid ink drops are formed of a solvent, a monomer, or a photoinitiator

10. A method of forming ink droplets on a substrate, suitable for use in semiconductor manufacturing, comprising:
forming a plurality of chemical stoppers on a top surface of the substrate, each chemical stopper of the plurality of chemical stoppers forming an outline around an opening and the opening exposing the top surface of the substrate;
depositing a plurality of liquid ink drops within the openings of the chemical stoppers; and
performing a thermal treatment on the liquid ink drops to form a plurality of solid ink drops, wherein the thermal treatment comprises heating the substrate to a temperature of about 50° C. to about 200° C. and each of the chemical stoppers have a first thickness of less than 100% of a second thickness of each of the solid ink drops.

11. The method of claim 10, wherein forming the plurality of chemical stoppers further comprises depositing the chemical stoppers using an ink jet.

12. The method of claim 10, wherein forming the plurality of chemical stoppers further comprises:
coating the top surface of the substrate with a resist material;
exposing portions of the resist material to radiation; and
patterning the resist material by removing one of the exposed portions of the resist material or unexposed portions of the resist material.

13. The method of claim 10, further comprising baking or ultra-violet curing the plurality of chemical stoppers.

14. The method of claim 13, wherein the plurality of chemical stoppers are baked at a temperature of about 50° C. to about 200° C.

15. The method of claim 10, wherein a surface tension of the chemical stoppers is less than about 25 mN/m.

16. The method of claim 10, wherein the chemical stoppers comprise a self-assembled monolayer and include a hydrophobic moiety disposed on a side of the self-assembled monolayer facing away from the substrate.

17. A non-transitory computer-readable medium storing instructions that, when executed by a processor, cause a computer system to perform the steps of:
forming a plurality of chemical stoppers on a top surface of a substrate, wherein each chemical stopper of the plurality of chemical stoppers comprises an opening;
depositing a plurality of liquid ink drops within the openings of the chemical stoppers; and
performing a thermal treatment on the liquid ink drops to cure the liquid ink drops and form a plurality of solid ink drops.

18. The medium of claim 17, wherein each of the chemical stoppers has a first thickness of less than 50% of a second thickness of each of the solid ink drops.

19. The medium of claim 17, wherein the thermal treatment is one of a bake or an ultraviolet cure.

20. The medium of claim 17, further comprising performing a first thermal treatment on the plurality of chemical stoppers before depositing the plurality of liquid ink drops.
